(19) United States
(12) Patent Application Publication
(10) Pub. No.: US 2025/0246447 A1
(43) Pub. Date: Jul. 31, 2025

(54) CHOKE PLATES FOR SEMICONDUCTOR MANUFACTURING PROCESSING CHAMBERS

(71) Applicant: Applied Materials, Inc., Santa Clara, CA (US)

(72) Inventors: Youngki Chang, Santa Clara, CA (US); Dhritiman Subha Kashyap, Bangalore (IN); Tejas Umesh Ulavi, Fremont, CA (US); Sanket S. Kurbet, Bangalore (IN); Ala Moradian, San Jose, CA (US)

(73) Assignee: Applied Materials, Inc., Santa Clara, CA (US)

(21) Appl. No.: 18/422,727

(22) Filed: Jan. 25, 2024

(51) Int. Cl. H01L 21/67; H01J 37/32

(52) U.S. Cl. CPC H01L 21/67017; H01J 37/3244; H01J 37/32899; H01J 2237/332

(57) ABSTRACT

Choke plates and semiconductor manufacturing processing chamber incorporating the choke plates are described. The choke plates include an opening extending through the body with a plurality of angled apertures extending from a gas plenum within the body to the inner face of the opening. The plurality of angled apertures are angled from the gas plenum toward the top surface of the body.

### TECHNICAL FIELD

Embodiments of the disclosure are directed to choke plates for semiconductor manufacturing processing chambers. In particular, embodiments of the disclosure are directed to choke plates with angled holes for multi-station processing chambers.

### BACKGROUND

Reliably producing submicron and smaller features is one of the key requirements of very large scale integration (VLSI) and ultra large scale integration (ULSI) of semiconductor devices. However, with the continued miniaturization of circuit technology, the dimensions of the size and pitch of circuit features, such as interconnects, have placed additional demands on processing capabilities. The various semiconductor components (e.g., interconnects, vias, capacitors, transistors) require precise placement of high aspect ratio features. Reliable formation of these components is critical to further increases in device and density.

Additionally, the electronic device industry and the semiconductor industry continue to strive for larger production yields while increasing the uniformity of layers deposited on substrates having increasingly larger surface areas. These same factors in combination with new materials also provide higher integration of circuits per unit area on the substrate.

As the dimensions of devices continue to shrink, so does the gap/space between the devices, increasing the difficulty to physically isolate the devices from one another. Filling in the high aspect ratio trenches/spaces/gaps between devices which are often irregularly shaped with high-quality dielectric materials is becoming an increasing challenge to implementation with existing methods including gap fill, hardmasks and spacer applications.

Conventional semiconductor manufacturing processing chambers exhibit asymmetrical pumping efficiency due to the non-symmetric arrangement of the chamber components. The non-symmetry results in non-uniformity of the pumping flow rate so that portions of the chamber near the pump have a higher flow rate than portions of the chamber further from the pump.

Accordingly, there is a need in the art for improved pumping in multi-station processing chambers.

### SUMMARY

One or more embodiments of the disclosure are directed to choke plates for a semiconductor manufacturing processing chamber. The choke plates comprise a body with an upper portion and a lower portion, a top surface and a bottom surface, and an opening extending through the body from the top surface to the bottom surface. The lower portion has a gas plenum within a thickness of the body. A plurality of angled apertures extend from the gas plenum to an inner face of the opening. The plurality of angled apertures are angled from the gas plenum toward the top surface of the body.

Additional embodiments of the disclosure are directed to processing chambers comprising a chamber body having a bottom and sidewalls surrounding a chamber interior. A substrate support is within the chamber interior. The substrate support has a support surface. An RF shield surrounds the support surface. The RF shield has an inner face spaced from an outer peripheral face of the support surface. A choke plate has an upper portion positioned on the chamber sidewall and a lower portion extending into the chamber interior adjacent the chamber sidewall. The choke plate comprises a body with an opening extending therethrough. The opening has an inner face spaced a distance from the outer face of the RF shield to form a gap. The choke plate has a gas plenum within a thickness of the body with a plurality of angled apertures extending from the gas plenum to an inner face of the opening. The plurality of angled apertures are angled from the gas plenum toward the support surface of the substrate support. A pumping ring is on a top surface of the choke plate. The pumping ring comprises a vacuum plenum configured to remove process gases from an interior of the processing chamber.

Further embodiments of the disclosure are directed to processing chambers comprising: a chamber body and a lid. The chamber body has a bottom and sidewalls surrounding a chamber interior. The lid is on the chamber body enclosing the chamber interior. The lid has a plurality of gas distribution assemblies arranged to create a plurality of process stations within the chamber interior. Each of the process stations comprise a substrate support, an RF shield, a choke plate and a pumping ring. The substrate support is within the chamber interior and has a support surface. The RF shield surrounds the support surface. The RF shield has an inner face spaced from an outer peripheral face of the support surface. The choke plate has an upper portion positioned on the chamber sidewall and a lower portion extending into the chamber interior adjacent the chamber sidewall. The choke plate comprises a body with an opening extending therethrough. The opening has an inner face spaced a distance from the outer face of the substrate support to form a gap. The choke plate has a gas plenum within a thickness of the body with a plurality of angled apertures extending from the gas plenum to an inner face of the opening. The plurality of angled apertures are angled from the gas plenum toward the support surface of the substrate support. The pumping ring is on a top surface of the choke plate. The pumping ring comprises a vacuum plenum configured to remove process gases from an interior of the processing chamber.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 shows a cross-sectional schematic view of a processing chamber in accordance with one or more embodiment of the disclosure;

FIG. 2 shows a cross-sectional schematic view of a gas distribution assembly in accordance with one or more embodiment of the disclosure;

FIG. 3 shows a cross-sectional schematic view of a portion of a processing chamber showing the gas flows in accordance with one or more embodiment of the disclosure;

FIG. 4 illustrates an isometric view of a choke plate according to one or more embodiment of the disclosure;

FIG. 5 illustrates an expanded view of a portion of a choke plate in accordance with one or more embodiment of the disclosure; and

FIG. 6 shows a view of a portion of a multi-station processing chamber with multiple choke plates according to one or more embodiment of the disclosure.

### DETAILED DESCRIPTION

Before describing several exemplary embodiments of the disclosure, it is to be understood that the disclosure is not limited to the details of construction or process steps set forth in the following description. The disclosure is capable of other embodiments and of being practiced or being carried out in various ways.

As used in this specification and the appended claims, the term “substrate” refers to a surface, or portion of a surface, upon which a process acts. It will also be understood by those skilled in the art that reference to a substrate can also refer to only a portion of the substrate, unless the context clearly indicates otherwise. Additionally, reference to depositing on a substrate can mean both a bare substrate and a substrate with one or more films or features deposited or formed thereon

A “substrate” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, amorphous silicon, doped silicon, germanium, gallium arsenide, glass, sapphire, and any other materials such as metals, metal nitrides, metal alloys, and other conductive materials, depending on the application. Substrates include, without limitation, semiconductor wafers. Substrates may be exposed to a pretreatment process to polish, etch, reduce, oxidize, hydroxylate, anneal, UV cure, e-beam cure and/or bake the substrate surface. In addition to film processing directly on the surface of the substrate itself, in the present disclosure, any of the film processing steps disclosed may also be performed on an underlayer formed on the substrate as disclosed in more detail below, and the term “substrate surface” is intended to include such underlayer as the context indicates. Thus, for example, where a film/layer or partial film/layer has been deposited onto a substrate surface, the exposed surface of the newly deposited film/layer becomes the substrate surface.

“Atomic layer deposition” or “cyclical deposition” as used herein refers to a process comprising the sequential exposure of two or more reactive compounds to deposit a layer of material on a substrate surface. “Atomic layer deposition” or “cyclical deposition” as used herein refers to a process comprising the sequential exposure of two or more reactive compounds to deposit a layer of material on a substrate surface. The substrate, or portion of the substrate, is exposed separately to the two or more reactive compounds which are introduced into a reaction zone of a processing chamber. In a time-domain ALD process, exposure to each reactive compound is separated by a time delay to allow each compound to adhere and/or react on the substrate surface and then be purged from the processing chamber. These reactive compounds are said to be exposed to the substrate sequentially. In a spatial ALD process, different portions of the substrate surface, or material on the substrate surface, are exposed simultaneously to the two or more reactive compounds so that any given point on the substrate is substantially not exposed to more than one reactive compound simultaneously. As used in this specification and the appended claims, the term “substantially” used in this respect means, as will be understood by those skilled in the art, that there is the possibility that a small portion of the substrate may be exposed to multiple reactive gases simultaneously due to diffusion, and that the simultaneous exposure is unintended.

In one aspect of a time-domain ALD process, a first reactive gas (i.e., a first precursor or compound A) is pulsed into the reaction zone followed by a first time delay. Next, a second precursor or compound B is pulsed into the reaction zone followed by a second delay. During each time delay, a purge gas, such as argon, is introduced into the processing chamber to purge the reaction zone or otherwise remove any residual reactive compound or reaction by-products from the reaction zone. Alternatively, the purge gas may flow continuously throughout the deposition process so that only the purge gas flows during the time delay between pulses of reactive compounds. The reactive compounds are alternatively pulsed until a desired film or film thickness is formed on the substrate surface. In either scenario, the ALD process of pulsing compound A, purge gas, compound B and purge gas is a cycle. A cycle can start with either compound A or compound B and continue the respective order of the cycle until achieving a film with the predetermined thickness.

In an embodiment of a spatial ALD process, a first reactive gas and second reactive gas (e.g., nitrogen gas) are delivered simultaneously to the reaction zone but are separated by an inert gas curtain and/or a vacuum curtain. The substrate is moved relative to the gas delivery apparatus so that any given point on the substrate is exposed to the first reactive gas and the second reactive gas. The gas curtain can be any suitable gas separation arrangement known to the skilled artisan. For example, in some embodiments of a spatial ALD process chamber, a gas curtain is formed by a combination of purge gas ports and vacuum ports to maintain separation between the reactive gases to prevent gas-phase reactions. In some embodiments of a spatial ALD process chamber, separate process stations are configured to form a mini-process environment within each station.

As used in this specification and the appended claims, the terms “reactive compound”, “reactive gas”, “reactive species”, “precursor”, “process gas” and the like are used interchangeably to mean a substance with a species capable of reacting with the substrate surface or material on the substrate surface in a surface reaction (e.g., chemisorption, oxidation, reduction, cycloaddition). The substrate, or portion of the substrate, is exposed sequentially to the two or more reactive compounds which are introduced into a reaction zone of a processing chamber.

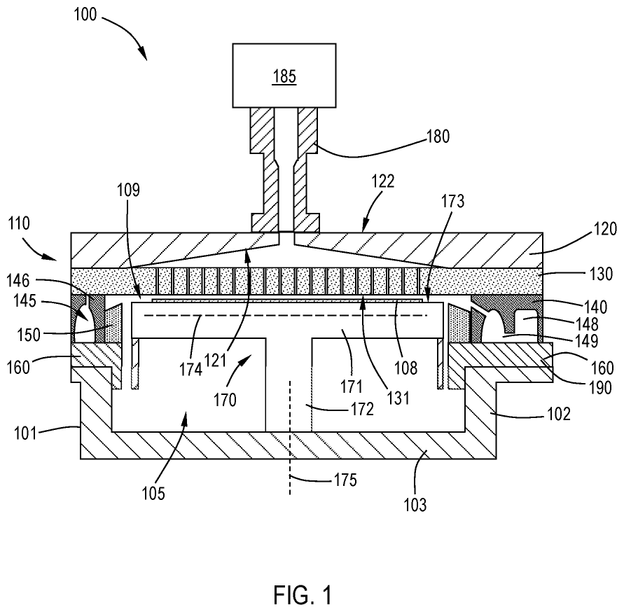

With reference to FIG. 1, one or more embodiments of the disclosure are directed to a semiconductor manufacturing processing chamber 100. The semiconductor manufacturing processing chamber 100 comprises a chamber body 101 having sidewalls 102 and a bottom wall 103 surrounding a chamber interior 105. The sidewall 102 and bottom wall 103 can be integrally formed or separate component connected together by any suitable connection or fastener known to the skilled artisan.

The semiconductor manufacturing processing chambers 100 of some embodiments includes a gas distribution assembly 110. The gas distribution assembly 110 comprises a backing plate 120 and a faceplate 130. In some embodiments, the processing chamber 100 further comprises a pumping ring 140. In some embodiments, the pumping ring 140 is considered a separate part from the gas distribution assembly 110.

Chamber body 101, in conjunction with the gas distribution assembly 110 encloses the chamber interior 105 of the semiconductor manufacturing processing chamber 100. During processing, the chamber interior 105 of the semiconductor manufacturing processing chamber 100 is typically maintained at a controlled pressure (usually a low-pressure environment) using one or more gas inlet (not shown) and one or more exhaust (not shown). The skilled artisan will be familiar with the general construction of the chamber body 101 and the use of gas inlets and exhaust systems.

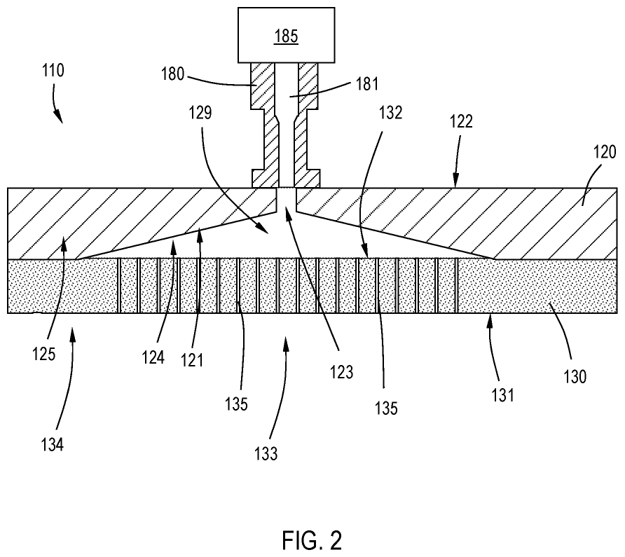

FIG. 2 illustrates a cross-sectional schematic representation of a gas distribution assembly 110 according to one or more embodiments of the disclosure. The backing plate 120 has a front surface 121 and a back surface 122 that define a thickness of the backing plate 120. The backing plate 120 has an inner portion 124 and an outer portion 125. The backing plate 120 contacts the faceplate 130 at the outer portion 125.

The backing plate 120 has an inlet opening 123 in a center thereof. The inlet opening 123 extends through the thickness of the backing plate 120 from the back surface 122 to the front surface 121. The central axis of the backing plate 120 is defined at the center of the inlet opening 123. The outer peripheral edge of the inner portion 124 of the front surface 121 of some embodiments is concentric with the inlet opening 123. While the backing plate 120 of some embodiments has an oblong or non-symmetrical shape, the central axis remains at the center of the inlet opening 123 even if that is not the center of mass of the backing plate 120.

The front surface 121 of the backing plate 120 at the inner portion 124 has a concave shape. The concave shape of some embodiments has a linear slope from the inlet opening 123 to the outer peripheral edge of the inner portion 124, as illustrated in the Figures. In some embodiments, the concave shape is curved from the inlet opening 123 to the outer peripheral edge of the inner portion 124.

The gas distribution assembly 110 includes a faceplate 130, which may also be referred to as a “showerhead”. The faceplate 130 has a front surface 131 and a back surface 132 defining a thickness of the faceplate 130. The faceplate 130 has an inner portion 133 and an outer portion 134. The inner portion 133 of the faceplate 130 aligns with the inner portion 124 of the backing plate 120 and the outer portion 134 of the faceplate 130 aligns with the outer portion 125 of the backing plate 120. The inner portion 133 of the faceplate 130 comprises a plurality of apertures 135 extending through the thickness of the faceplate 130.

The backing plate 120 can be connected to the faceplate 130 by any suitable mechanism known to the skilled artisan. For example, the backing plate 120 can be welded to the faceplate 130. In some embodiments, the backing plate 120 is connected to the faceplate 130 with a plurality of fasteners. Suitable fasteners include, but are not limited to, bolts with or without O-rings.

When the front surface 121 of the outer portion 125 of the backing plate 120 is in contact with the outer portion 134 of the back surface 132 of the faceplate 130, a gas box plenum 129 is formed in the space between the front surface 121 of the inner portion 124 of the backing plate 120 and the inner portion 133 of the back surface 132 of the faceplate 130.

In some embodiments, the gas box plenum 129 has a coating to improve chemical compatibility. In some embodiments, the coating covers the entire front surface 121 of the backing plate 120 and the entire back surface 132 of the faceplate 130, including in the inlet opening 123 of the backing plate 120 and the plurality of apertures 135 of the faceplate 130. In some embodiments, the coating is only on the portions of the backing plate 120 and faceplate 130 that will come into contact with the process gases.

In some embodiments, the gas distribution assembly 110 further comprises an inlet flange 180 connected to the back surface 122 of the backing plate 120. The inlet flange 180 has an inner channel 181 aligned with the opening 123 in the center of the backing plate 120. The inner channel 181 of some embodiments has an upper portion and a lower portion. The upper portion has a larger inner diameter than an inner diameter of the lower portion, as illustrated in FIG. 2.

Some embodiments of the semiconductor manufacturing processing chamber 100 further comprise a remote plasma source (RPS) 185 connected to the inlet flange 180. In use, a plasma generated in the remote plasma source 185 flows through the inlet flange 180 into the gas box plenum 129. In some embodiments, an inert gas purge line (not shown) is connected to the inner channel 181 of the inlet flange 180 to provide a continuous inert gas purge to prevent back streaming of gases to the remote plasma source 185. In some embodiments, inclusion of the inert gas purge eliminates the need for an isolation valve through continuous inert gas purge.

The semiconductor manufacturing processing chamber 100 comprises a substrate support 170 within the chamber interior 105. The substrate support 170 of some embodiments comprises a support body 171 positioned on a support shaft 172. The support body 171 has a support surface 173 configured to support a semiconductor wafer 108 for processing. The support shaft 172 of some embodiments is configured to move the support body 171 closer to/further from the faceplate 130 and/or around a rotational axis 175 of the support shaft 172. During processing, the support surface 173 is spaced from the front surface 131 of the faceplate 130 to form a process gap 109.

In some embodiments, the support body 171 includes a thermal element 174 configured to heat the semiconductor wafer 108 on the support surface 173. The thermal element 174 can be any suitable heating mechanism known to the skilled artisan. For example, in some embodiments, the thermal element 174 comprises a resistive heating element that is connected to a power supply (not shown) configured to apply power to the thermal element 174 to heat the support body 171. In some embodiments, the support body 171 includes an electrostatic chuck (ESC) (not shown). The skilled artisan will be familiar with the construction of the ESC and the manner in which the ESC is powered and employed.

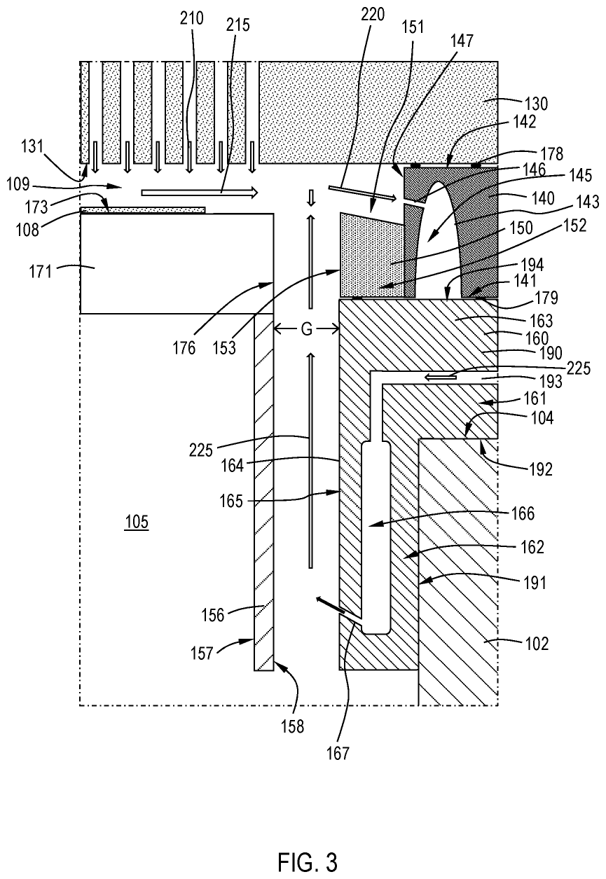

FIG. 3 illustrates a schematic view of a portion of a semiconductor manufacturing processing chamber 100 in accordance with one or more embodiments of the disclosure. In some embodiments, as shown in FIGS. 1 and 3, the semiconductor manufacturing processing chamber 100 includes a radio-frequency (RF) shield 150. The RF shield 150 is a generally ring-shaped component that is positioned within the interior 105 of the semiconductor manufacturing processing chamber 100 between the substrate support 170 and the sidewall 102. The RF shield 150 surrounds the support surface 173 of the substrate support 170 and helps to prevent reactive gases from flowing from the process gap 109 to the interior 105 of the chamber body 101.

The RF shield 150 has a top end 151 and a bottom end 152. The top end 151 of some embodiments has a sloped surface configured to direct a gas flow toward the pumping ring 140. In some embodiments, the top end 151 of the RF shield 150 has a top end surface that is coplanar with the support surface 173 of the substrate support 170. In some embodiments, where the top end surface of the RF shield 150 is sloped, as shown in the Figures, the highest point of the top end surface is coplanar with the support surface 173 of the substrate support 170. In some embodiments, the top end 151 of the RF shield 150 has a top end surface that is below the level of the support surface 173.

In the illustrated embodiment, a heater cover 156 extends downward into the chamber interior 105 and is spaced a distance from the sidewall 102 of the chamber. The heater cover 156 has an inner face 157 and an outer face 158. In some embodiments, the heater cover 156 is considered part of the substrate support 170 and is coplanar with the outer peripheral face 176 of the substrate support 170. The gap G between the inner face 165 of the choke plate 160 and the outer peripheral face 176 of the substrate support 170, or the gap G between the inner face 165 of the choke plate 160 and the outer face 158 of the heater cover 156, in some embodiments, are the same. In some embodiments, the gap G between the inner face 165 of the choke plate 160 and the outer peripheral face 176 of the substrate support 170, or between the inner face 165 of the choke plate 160 and the outer face 158 of the heater cover 156, is in the range of 0.5 to 20 mm, or in the range of 1 to 10 mm.

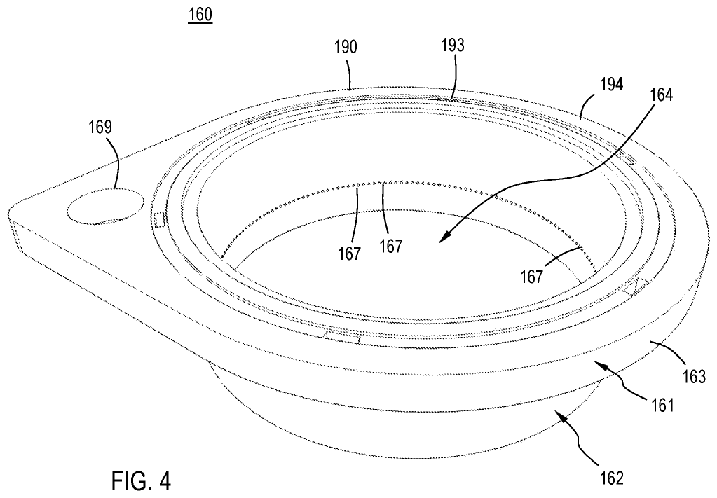

FIG. 4 shows an isometric view of a choke plate 160 in accordance with one or more embodiments of the disclosure. With reference to FIGS. 1, 3 and 4, the semiconductor manufacturing processing chamber 100 of some embodiments includes a choke plate 160. The choke plate 160 has an upper portion 161 and a lower portion 162. The upper portion 161 of the choke plate 160 is positioned on the chamber sidewall 102 and the lower portion 162 extends into the chamber interior 105 adjacent the chamber sidewall 102. The choke plate 160 comprises a body 163 with an opening 164 extending therethrough. The opening 164 has an inner face 165 with an inner diameter.

In the semiconductor manufacturing processing chamber 100, the choke plate 160 is positioned so that the inner face 165 is spaced a distance from the outer face 158 of the heater cover 156 to form a gap G. In some embodiments, the RF shield 150 has an inner face 153 spaced a distance from the outer peripheral face 176 of the substrate support 170 to form a gap. In some embodiments, the gap between the substrate support and the RF shield 150 has a width within 0.1 mm of the width of the gap G between the outer face 158 of the heater cover 156 and the inner face 165 of the choke plate 160.

The choke plate 160 has a gas plenum 166 within a thickness of the body 163. A plurality of angled apertures 167 extend from the gas plenum 166 to the inner face 165 of the opening 164.

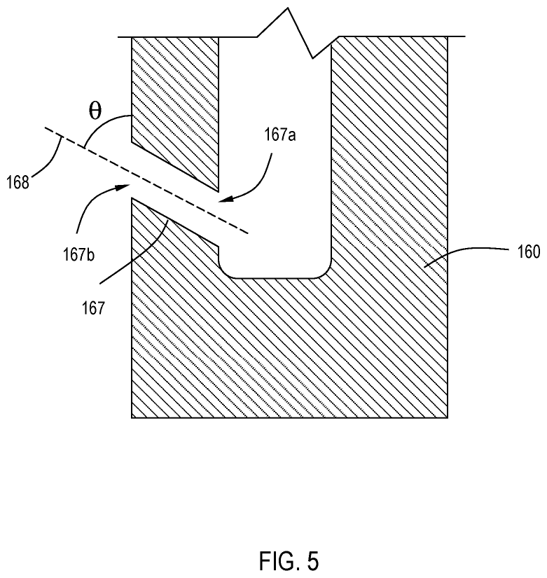

FIG. 5 shows an expanded schematic view of a portion of a choke plate 160 showing the gas plenum 166 and plurality of angled apertures 167. The plurality of angled apertures 167 are angled from the gas plenum 166 toward the support surface 173 of the substrate support 170. Stated differently, the plurality of angled apertures 167 extend from a gas plenum end 167a to an inner face end 167b, where the inner face end 167b is closer to the support surface 173 of the substrate support 170 than the gas plenum end 167a of the plurality of angled apertures 167.

The plurality of angled apertures 167 are angled relative to the inner face 165 of the choke plate 160, with an aperture extending normal to the inner face 165 being considered as 90°. As used in this specification and the appended claims, the term “angled aperture” means that the axis 168 of the plurality of angled apertures 167 form an angle less than 85°, or less than 80°, or less than 75° measured toward the support surface 173 of the substrate support 170, or the upper portion 161 of the choke plate 160. In some embodiments, the plurality of angled apertures 167 have an angle Θ in the range of 10° to 75°, or in the range of 15° to 60°, or in the range of 20° to 55°, or in the range of 25° to 50°, or in the range of 30° to 50°, or in the range of 40° to 50°.

In some embodiments, the plurality of angled apertures 167 comprise in the range of 10 to 1000 apertures, or in the range of 25 to 500 apertures, or in the range of 50 to 500 apertures, or in the range of 50 to 250 apertures, or in the range of 60 to 200 apertures, or in the range of 70 to 180 apertures.

In some embodiments, the angled apertures 167 have a diameter in the range of 0.25 mm to 5 mm, or in the range of 0.5 mm to 4.5 mm, or in the range of 0.75 mm to 4 mm, or in the range of 1 mm to 3.5 mm, or in the range of 1.5 mm to 3.25 mm, or in the range of 2 mm to 3 mm.

In some embodiments, the plurality of angled apertures 167 are evenly spaced around the inner face 165 of the 164 opening in the body 163 of the choke plate 160. In some embodiments, the plurality of angled apertures 167 are variably spaced around the inner face 165. For example, in some embodiments, there are more apertures on the side of the opening 164 opposite the exhaust port 169 which is in fluid communication with an exhaust or vacuum system.

As shown in the illustrated embodiments, the upper portion 161 of the choke plate 160 has a flange 190 that extends outwardly from the outer face 191 of the lower portion 162 of the body 163 of the choke plate 160. In some embodiments, the flange 190 has a bottom face 192 that is in contact with the top surface 104 of the chamber sidewall 102.

In some embodiments, as shown in FIG. 3, the choke plate 160 includes an inlet line 193 extending into the body 163 of the choke plate 160. The inlet line 193 is in fluid communication with the gas plenum 166 to provide a flow of gas (e.g., an inert gas or purge gas) into the gas plenum 166. In the illustrated embodiment, the inlet line 193 extends from an outside portion of the upper portion 161 of the body 163. In some embodiments, the inlet line 193 extends from an inlet line opening in the top surface 194 of the choke plate 160, as shown in FIG. 4.

A pumping ring 140 is positioned on a top surface 194 of the choke plate 160. The pumping ring 140 has a front surface 141 and a back surface 142 defining a thickness of the pumping ring 140. In use, the back surface of the pumping ring 140 is positioned adjacent to or in contact with the front surface 131 of the faceplate 130. In some embodiments, in use, the front surface 141 of the pumping ring 140 is positioned in contact with the top surface 194 of the choke plate 160.

The pumping ring 140 comprises a vacuum plenum configured to remove process gases from an interior of the processing chamber. The vacuum plenum is formed by the recess in the front surface 141 of the pumping ring 140 when the front surface 141 of the pumping ring 140 is adjacent another surface. For example, as shown in FIGS. 1 and 3, when the pumping ring 140 is positioned so that the front surface 141 is adjacent to or in contact with the choke plate 160 or chamber sidewall 102, a pumping volume 145 is formed.

In some embodiments, the pumping ring 140 is connected to the backing plate 120 with a plurality of fasteners (not shown) that extend through the faceplate 130. In some embodiments, bolting the backing plate 120 to the pumping ring 140 sandwiches the faceplate 130 between the backing plate 120 and the pumping ring 140.

In some embodiments, at least one aperture 146 extends between the recess 143 in the front surface 141 of the pumping ring 140 and the back surface 142 of the pumping ring 140. In some embodiments, the at least one aperture 146 extends between the recess 143 in the front surface 141 of the pumping ring 140 and an inner face 147 of the pumping ring 140. The at least one aperture 146 has a radius equal to a radius of the front surface opening of the angled openings 137 in the faceplate 130.

In some embodiments, the pumping ring 140 has a non-symmetrical shape. For example, as shown in the Figures, one side or portion of the pumping ring 140 extends further from the central axis of the pumping ring 140. As shown in FIG. 1, the right side of the pumping ring 140 extends further from the central axis than the left side of the pumping ring 140. This can be, for example, to accommodate an exhaust recess 148 which, when the pumping ring 140 is positioned on the sidewall 102 of the processing chamber body 101 or on the top surface 194 of the choke plate 160, creates an exhaust plenum. The exhaust plenum is connected to the pumping volume 145 by one or more exhaust channels 149. The exhaust channels 149 of some embodiments are formed as one or more recess in the front surface 141 of the pumping ring 140 connecting the recess 143 with the exhaust recess 148. In some embodiments, the shape of the pumping ring 140 allows for symmetrical or asymmetrical placement of multiple exhaust recesses 148 around the periphery of the pumping ring 140.

During use, the backing plate 120, faceplate 130 and pumping ring 140, in addition to other components, may be separated by one or more O-rings to help maintain a fluid-tight seal for the processing chamber. In some embodiments, the gas distribution assembly 110 includes a plurality of O-rings 178 positioned between the backing plate 120 and the faceplate 130 and/or a plurality of O-rings 178 positioned between the faceplate 130 and the pumping ring 140. In some embodiments, the pumping ring 140 is connected to the choke plate 160 with at least one O-ring 179 positioned between.

Referring again to FIG. 3, when in use, process gases 210 flow into process gap 109 through faceplate 130. In process gap 109, the process gases 215 flow across the surface of the semiconductor wafer 108 toward the RF shield 150 and the gap between the RF shield 150 and the outer peripheral face 176 of the substrate support 170. At least some of the process gases 220 flow over the top end 151 of the RF shield 150 toward at least one aperture 146 in the pumping ring 140 to be exhausted through pumping volume 145 from the semiconductor manufacturing processing chamber 100. To prevent gases flowing into the chamber interior 105 through the gap G, purge gases are added to the gap G through the choke plate 160. Inert gas 225 (or purge gas) flow into gas plenum 166 through inlet line 193. The inert gas 225 then flows through the plurality of angled apertures 167 into the gap G angled toward the top end 151 of the RF shield 150. The inert gas 225 flow helps ensure that the process gases 220 flows towards pumping ring 140 and not into the chamber interior 105.

Some embodiments of the disclosure are directed to multi-station processing chambers, also referred to as batch processing chambers. In an exemplary four station chamber, purge gas is applied at each station's choke plate to prevent precursor diffusion from the process station to the bottom of the chamber interior. The center of the station has more open space than edge space. This geometrical non symmetry causes purge gas non uniformity to the pumping liner. To mitigate pumping non-uniformity or compensate chamber geometrical non-symmetry, embodiments of the disclosure advantageously use angled purge hole incorporated into the choke plate resulting in improved pumping uniformity.

The angled purge hole at choke plate makes recirculation flow and isolate chamber top/bottom so compensate chamber geometrical non-symmetry. Flow simulation using a split flow (a top flow and a bottom flow) with the current 90 degree (normal to the choke plate surface) purge holes illustrates that the down flow is not uniform due to non-symmetric chamber geometry.

The inventors have surprisingly found that angling the purge holes of the choke plate decreases the mass flow non-uniformity around the process station. In some embodiments, the pumping non-uniformity around an upper periphery of each of the choke plates is less than 5%. In some embodiments, the pumping non-uniformity around an upper periphery of each of the choke plates is less than or equal to 4.5%, 4%, 3.5%, 3%, 2.75% or 2.5%. In some embodiments, the uniformity of gases leaking from the gap into the chamber interior is improved relative to a choke plate with apertures extending normal to the inner face of the opening in the choke plate.

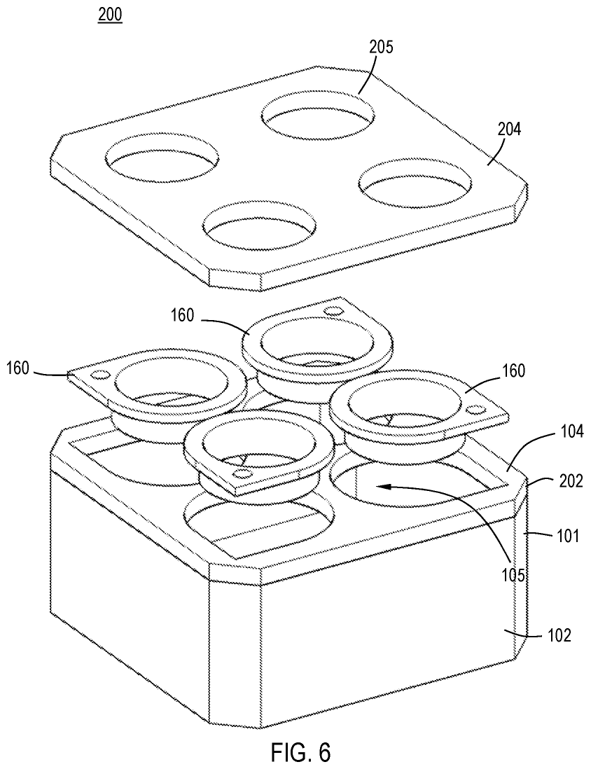

Accordingly, some embodiments of the disclosure are directed to multi-station processing chambers. FIG. 6 shows an exploded view of a portion of a multi-station processing chamber. The multi-station processing chamber 200 comprises more than one semiconductor manufacturing processing chambers 100. The chamber body 101 has sidewalls 102 and a top surface 104 enclosing the chamber interior 105. In the illustrated embodiment, a sidewall plate 202 is positioned on the sidewalls 102 as either a separate component or a single component with the sidewalls 102. Each station of the multi-station processing chamber has a substrate support 170. In some embodiments, the substrate supports are connected together into a single assembly that can spin around a central axis so that all of the support surfaces move together. A lid 204 is on the chamber body enclosing the chamber interior 105. The lid 204 has a plurality of openings 205 that can be sized to support a gas distribution assembly 110. The skilled artisan will recognize the manner in which the individual components of the gas distribution assembly 110, as shown in FIG. 1, can be arranged in the openings 205 in the lid 204. In the illustrated embodiment, four choke plates 160 are arranged around the interior of the processing chamber. Each of the choke plate 160 are aligned with the openings 205 in the lid 204 to create a process station. Each of the choke plates 160 can be connected to the same purge gas source or different purge gas sources during processing.

Reference throughout this specification to “one embodiment,” “certain embodiments,” “one or more embodiments” or “an embodiment” means that a particular feature, structure, material, or characteristic described in connection with the embodiment is included in at least one embodiment of the disclosure. Thus, the appearances of the phrases such as “in one or more embodiments,” “in certain embodiments,” “in one embodiment” or “in an embodiment” in various places throughout this specification are not necessarily referring to the same embodiment of the disclosure. Furthermore, the particular features, structures, materials, or characteristics may be combined in any suitable manner in one or more embodiments.

Although the disclosure herein has been described with reference to particular embodiments, those skilled in the art will understand that the embodiments described are merely illustrative of the principles and applications of the present disclosure. It will be apparent to those skilled in the art that various modifications and variations can be made to the method and apparatus of the present disclosure without departing from the spirit and scope of the disclosure. Thus, the present disclosure can include modifications and variations that are within the scope of the appended claims and their equivalents.

What is claimed is:

1. A choke plate for a semiconductor manufacturing processing chamber, the choke plate comprising:
a body with an upper portion and a lower portion, a top surface and a bottom surface, and an opening extending through the body from the top surface to the bottom surface, the lower portion having a gas plenum within a thickness of the body, and a plurality of angled apertures extending from the gas plenum to an inner face of the opening, the plurality of angled apertures are angled from the gas plenum toward the top surface of the body.

2. The choke plate of claim 1, wherein the plurality of angled apertures comprise in the range of 50 to 500 apertures.

3. The choke plate of claim 1, wherein the plurality of angled apertures have an angle in the range of 10 to 75°.

4. The choke plate of claim 1, wherein the plurality of angled apertures are evenly spaced around the inner face of the opening in the body.

5. The choke plate of claim 1, wherein the upper portion of the body has a flange extending outwardly from an outer face of the lower portion of the body.

6. The choke plate of claim 1, further comprising an inlet line extending into the body of the choke plate, the inlet line in fluid communication with the gas plenum.

7. A processing chamber comprising:
a chamber body having a bottom and sidewalls surrounding a chamber interior,
a substrate support within the chamber interior, the substrate support having a support surface;
an RF shield surrounding the support surface, the RF shield having an inner face spaced from an outer peripheral face of the support surface;
a choke plate having an upper portion positioned on the chamber sidewall and a lower portion extending into the chamber interior adjacent the chamber sidewall, the choke plate comprising a body with an opening extending therethrough, the opening having an inner face spaced a distance from the outer face of the RF shield to form a gap, the choke plate having a gas plenum within a thickness of the body with a plurality of angled apertures extending from the gas plenum to an inner face of the opening, the plurality of angled apertures are angled from the gas plenum toward the support surface of the substrate support; and
a pumping ring on a top surface of the choke plate, the pumping ring comprising a vacuum plenum configured to remove process gases from an interior of the processing chamber.

8. The processing chamber of claim 7, wherein the gas plenum is within the lower portion of the choke plate.

9. The processing chamber of claim 7, wherein the plurality of angled apertures comprises in the range of 50 to 500 apertures.

10. The processing chamber of claim 7, wherein the plurality of angled apertures have an angle in the range of 10° to 75°.

11. The processing chamber of claim 7, wherein the plurality of angled apertures are evenly spaced around the inner face of the opening in the body.

12. The processing chamber of claim 7, wherein the upper portion of the body has a flange extending outwardly from an outer face of the lower portion of the body.

13. The processing chamber of claim 7, further comprising an inlet line extending into the body of the choke plate, the inlet line in fluid communication with the gas plenum.

14. The processing chamber of claim 7, wherein the gap is in the range of 1 to 10 mm.

15. The processing chamber of claim 7, wherein uniformity of gases leaking from the gap into the chamber interior is improved relative to a choke plate with apertures extending normal to the inner face of an opening in the choke plate.

16. The processing chamber of claim 7, wherein pumping non-uniformity around an upper periphery of the choke plate is less than 5%.

17. A processing chamber comprising:
a chamber body having a bottom and sidewalls surrounding a chamber interior;
a lid on the chamber body enclosing the chamber interior, the lid having a plurality of gas distribution assemblies arranged to create a plurality of process stations within the chamber interior, each process station comprising:
a substrate support within the chamber interior, the substrate support having a support surface;
an RF shield surrounds the support surface, the RF shield having an inner face spaced from an outer peripheral face of the support surface;
a choke plate having an upper portion positioned on the chamber sidewall and a lower portion extending into the chamber interior adjacent the chamber sidewall, the choke plate comprising a body with an opening extending therethrough, the opening having an inner face spaced a distance from the outer peripheral face of the support surface to form a gap, the choke plate having a gas plenum within a thickness of the body with a plurality of angled apertures extending from the gas plenum to an inner face of the opening, the plurality of angled apertures are angled from the gas plenum toward the support surface of the substrate support; and
a pumping ring on a top surface of the choke plate, the pumping ring comprising a vacuum plenum configured to remove process gases from an interior of the processing chamber.

18. The processing chamber of claim 17, wherein the plurality of angled apertures comprises in the range of 50 to 500 apertures.

19. The processing chamber of claim 17, wherein the plurality of angled apertures have an angle in the range of 10° to 75°.

20. The processing chamber of claim 7, wherein the gap is in the range of 1 mm to 10 mm and pumping non-uniformity around an upper periphery of each of the choke plates is less than 5%.
